(19) United States
(12) Patent Application Publication
(10) Pub. No.: US 2026/0333618 A1
(43) Pub. Date: Oct. 22, 2026

(54) EFFICIENT COOLING CASE

(71) Applicant: DONGGUAN SHUOYI HARDWARE MANUFACTURING CO., LTD., DONGGUAN (CN)

(72) Inventor: Haidan Fei, Yueyang (CN)

(21) Appl. No.: 19/692,546

(22) Filed: May 29, 2026

(30) Foreign Application Priority Data
Mar. 26, 2026 (CN) 202620388250.5

(51) Int. Cl. H05K 7/20

(52) U.S. Cl. CPC H05K 7/20172; H05K 7/20145

(57) ABSTRACT

Provided is an efficient cooling case, which includes a casing, an installation plate is installed inside the casing, and heat dissipation holes are provided on a right side plate of the casing. The installation plate is provided with a fixing plate, and the fixing plate is provided with an air inlet and heat dissipation module. A rear side plate of the casing is provided with a rear heat dissipation mesh that is provided with an air outlet and heat dissipation module; the air inlet and/or outlet heat dissipation modules include at least two detachable module fans; two opposite sides of a frame of each of the modular fans are respectively provided with a conductive male terminal and a conductive female terminal, and the two opposite sides of the frame of each of the modular fan are respectively provided with a splicing block and a splicing slot.

### CROSS-REFERENCE TO RELATED APPLICATIONS

This application claims priority to Chinese Patent Application No. 202620388250.5, filed on Mar. 26, 2026, which is hereby incorporated by reference in its entirety.

### TECHNICAL FIELD

The present disclosure relates to the field of case technologies, and in particular, to an efficient cooling case.

### BACKGROUND

With the rapid development of 5G communication, AI computing chips, and high-performance computing devices, the power consumption and heat flux density of electronic devices continue to rise. As the installation carrier of electronic components, the cooling performance of the computer case directly determines the operational stability, service life, and work efficiency of internal motherboards, chips, and other electrical components, and has become one of the core considerations in the field of case design. At present, most computer cases on the market use fans as the core cooling components, thus forming a cooling airflow through a single fan or a combination of multiple fans to dissipate heat inside the case. Where, multi fan combination cooling is widely used in high-performance computers, servers and other devices with high cooling requirements because it can provide larger air volume.

However, there are still many technical defects in the existing multi fan combination cooling case, which are difficult to meet the increasing demand for cooling and user experience. On the one hand, existing multi fan combinations are mostly fixed installation structures, lacking flexible splicing and assembly designs between fans. The assembly process is cumbersome, and the number of fans is fixed, rendering it difficult to flexibly increase or decrease according to the size specifications of the case, the heating power of internal electronic components, and actual application scenarios. Universality and adaptability are poor. When the heating load changes, it is difficult to achieve precise matching between heat dissipation effect and energy consumption. Either insufficient heat dissipation leads to component overheating, or redundant fans cause energy waste and increased noise.

On the other hand, in existing multi fan combinations, the installation direction and blade rotation direction of adjacent fans are often set uniformly. This layout can easily lead to convective collisions between the airflow generated by adjacent fans when they intersect, thereby forming obvious airflow disturbances. This not only reduces the airflow efficiency and weakens the cooling pressure but also generates significant wind noise due to the impact of airflow on each other, thus affecting the user experience. This problem is particularly prominent in scenarios with high noise requirements.

Therefore, the defects are obvious and there is an urgent need to provide a solution.

### SUMMARY

In order to solve the above technical problems, the purpose of the present disclosure is to provide an efficient cooling case.

In order to achieve the above objectives, the present disclosure is implemented as follows.

An efficient cooling case, including: a square casing, and the casing is provided with an installation plate inside, an installation space is formed between the installation plate and a right side plate of the casing; the right side plate of the casing is provided with heat dissipation holes, and the installation plate is integrally bent and formed with a fixing plate; the heat dissipation holes correspond to the fixing plate, and the fixing plate is detachably provided with an air inlet and heat dissipation module; the air inlet and heat dissipation module is provided between the installation plate and a front side plate of the casing, a rear side plate of the casing is provided with a rear heat dissipation mesh, and the rear heat dissipation mesh is detachably provided with an air outlet and heat dissipation module; the air inlet and heat dissipation module and/or the air outlet and heat dissipation module include at least two module fans that are configured to be disassembled and spliced together; a frame of each of the module fans is square shaped, and two opposite sides of the frame of each of the module fans are respectively provided with a conductive male terminal and a conductive female terminal; two opposite sides of the frame of each of the module fans are respectively provided with a splicing clamp block and a splicing clamp slot; the splicing clamp block and the conductive female terminal are provided on the same side of the module fans, and the splicing clamp slot and the conductive male terminal are provided on the same side of the module fans; in two adjacent module fans, the splicing clamp block of one module fan is clamp connected to the splicing clamp slot of the other module fan, and the conductive female terminal of one module fan is adapted and electrically connected to the conductive male terminal of the other module fan; two adjacent module fans are symmetrically arranged in a mirror image, and rotation directions of fan blades of the two adjacent module fans are opposite.

In some embodiments of the present disclosure, all module fans in the air inlet and heat dissipation module or the air outlet and heat dissipation module are arranged in a straight line.

In some embodiments of the present disclosure, other two opposite sides of the frame of each of the module fans is further provided with the conductive male terminal and the conductive female terminal, and other two opposite sides of the frame of each of the module fans is further provided with the splicing clamp block and the splicing clamp slot; the splicing clamp block and the conductive female terminal are provided on the same side of the module fans, and the splicing clamp slot and the conductive male terminal are provided on the same side of the module fans; the number of module fans in the air inlet and heat dissipation module or the air outlet and heat dissipation module are 2N, N≥2, where N is a positive integer, all module fans in the air inlet and heat dissipation module or the air outlet and heat dissipation module are arranged in a rectangular array.

In some embodiments of the present disclosure, the fixing plate and the rear heat dissipation mesh are both provided with multiple sets of clamp slot positions, and the module fans are provided with a clamp joint shaft configured to clamp connection with a set of clamp slot positions.

In some embodiments of the present disclosure, each set of clamp slot positions has multiple clamp slots, and the clamp joint shaft has multiple clamp shafts that are respectively connected to the multiple clamp slots.

In some embodiments of the present disclosure, the frame of each of the module fans is provided with magnetic suction components and at least two positioning columns, the fixing plate and the rear heat dissipation mesh are both provided with multiple positioning holes, and the magnetic suction components are configured to be magnetically attracted to the fixing plate or the rear heat dissipation mesh, and one positioning column and one positioning hole are concave and convex adapted.

In some embodiments of the present disclosure, the module fans are fixed to the fixing plate or the rear heat dissipation mesh by a locking fastener.

In some embodiments of the present disclosure, a top side plate of the casing is provided with a top heat dissipation mesh, a bottom side plate of the casing is provided with a bottom heat dissipation mesh, the top heat dissipation mesh is detachably provided with the air inlet and heat dissipation module, and the bottom heat dissipation mesh is detachably provided with the air outlet and heat dissipation module.

In some embodiments of the present disclosure, the fixing plate is arranged to be inclined relative to the installation plate, and an angle between the fixing plate and the front side plate of the casing is obtuse.

In some embodiments of the present disclosure, a circular arc air guide plate is provided at an angle between the front side plate of the casing and the left side plate of the casing.

The beneficial effects of the present disclosure are as follows: in practical applications, a motherboard and other electrical components are installed in the installation space. When the motherboard and other electrical components work, they generate a large amount of heat. The air inlet and heat dissipation module and the air outlet and heat dissipation module are activated. The air inlet-and-heat dissipation module forms an airflow of external air, and the airflow enters the casing, and the air outlet and heat dissipation module blows the airflow inside the casing out of the casing. This airflow can quickly dissipate the heat inside the casing; where in the air inlet and heat dissipation module and the air outlet and heat dissipation module, due to the mirror setting of adjacent module fans and the opposite rotation directions of the fan blades of adjacent module fans, a convergence space is formed between adjacent module fans. Therefore, the airflow generated by adjacent module fans flows in the same direction through the convergence space, and there is no convective collision between the two airflows during convergence, effectively reducing turbulence, enhancing wind pressure, and reducing wind noise, thereby improving the cooling effect. In addition, since the adjacent two module fans in the air inlet and heat dissipation module and the air outlet and heat dissipation module are assembled and disassembled quickly, it is not only beneficial for the assembly and molding of the air inlet and heat dissipation module and air outlet and heat dissipation module, but also allows for the increase or decrease of the number of the module fans according to the size and application scenario of the casing, in order to meet the needs of rapid cooling of the case. The present disclosure forms a fast-cooling airflow through collaborative work of the air inlet and heat dissipation module and the outlet cooling module. Combined with the opposite rotation directions of the fan blades of adjacent module fans, it greatly reduces turbulence, enhances wind pressure, and reduces wind noise, thereby improving the cooling effect. The module fans can be flexibly spliced, and the number of the module fans can be increased or decreased according to actual needs to ensure efficient cooling and facilitate the replacement and maintenance of individual module fans.

### BRIEF DESCRIPTION OF DRAWINGS

FIG. 1 is a three-dimensional structural schematic diagram behind a left side plate of a hidden casing in an embodiment provided by the present disclosure.

FIG. 2 is a three-dimensional structural schematic diagram of the embodiment provided by the present disclosure.

FIG. 3 is a three-dimensional structural schematic diagram from another perspective of the embodiment provided by the present disclosure.

FIG. 4 is a three-dimensional structural schematic diagram of an installation plate and a fixing plate provided by the present disclosure.

FIG. 5 is a three-dimensional structural schematic diagram of an air inlet and heat dissipation module and an air outlet and heat dissipation module of the embodiment provided by the present disclosure.

FIG. 6 is a three-dimensional structural schematic diagram of a module fan in the embodiment provided by the present disclosure.

FIG. 7 is a three-dimensional structural schematic diagram from another perspective of the module fan in the embodiment provided by the present disclosure.

FIG. 8 is a three-dimensional structural schematic diagram of the module fan in an another embodiment provided by the present disclosure.

FIG. 9 is a three-dimensional structural schematic diagram of the air inlet and heat dissipation module and an air outlet and heat dissipation module in a still one embodiment provided by the present disclosure.

Numeral reference: 1—casing, 2—installation plate, 3—heat dissipation hole, 4—fixing plate, 5—air inlet and heat dissipation module, 6—rear heat dissipation mesh, 7—air outlet and heat dissipation module, 8—module fan, 9—conductive male terminal, 10—conductive female terminal, 11—splicing clamp block, 12—splicing clamp slot, 13—locking fastener, 14—clamp joint shaft, 15—top heat dissipation mesh, 16—bottom heat dissipation mesh.

### DESCRIPTION OF EMBODIMENTS

In order to facilitate the understanding of technical personnel in this field, further explanation of the present disclosure is provided below in combination with the embodiments and accompanying drawings. The content mentioned in the embodiments is not a limitation of the present disclosure.

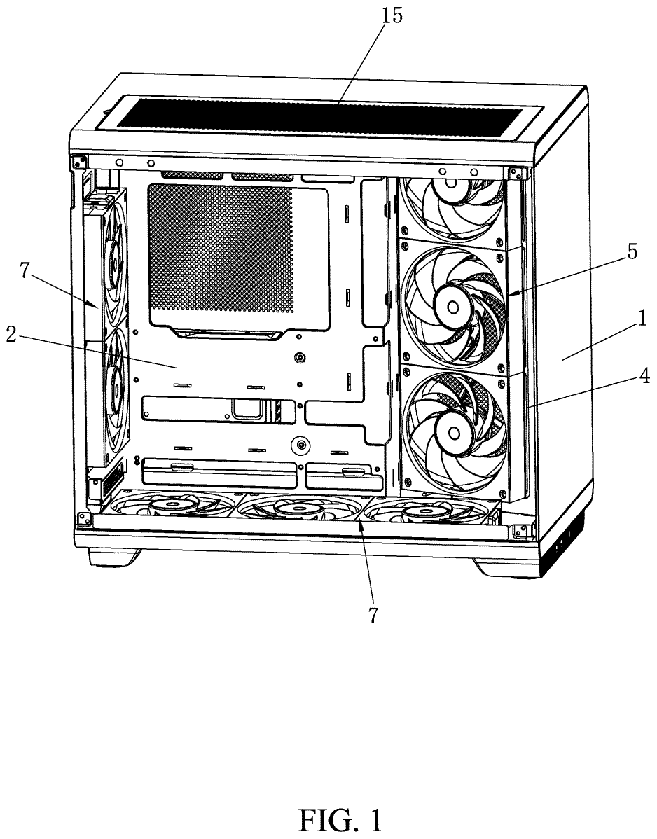

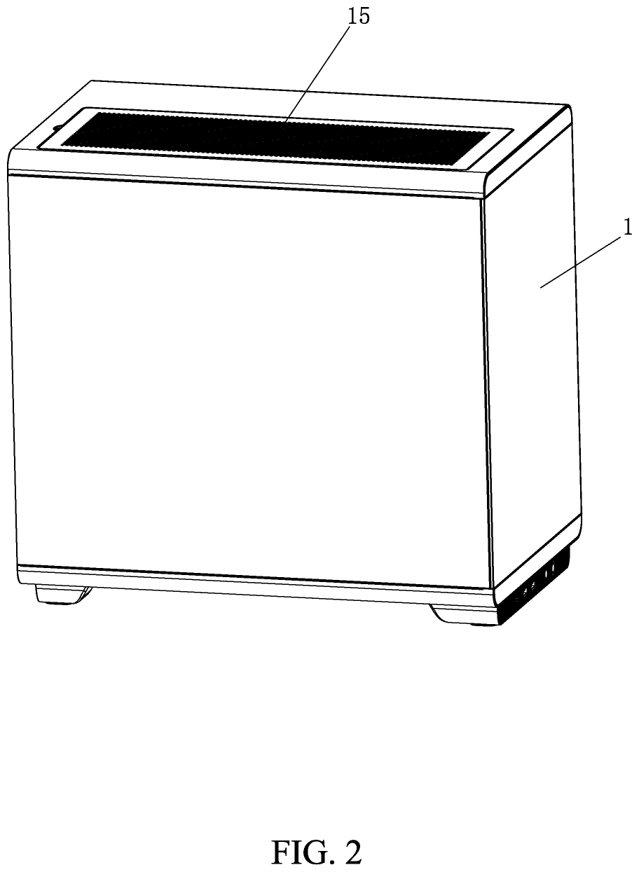

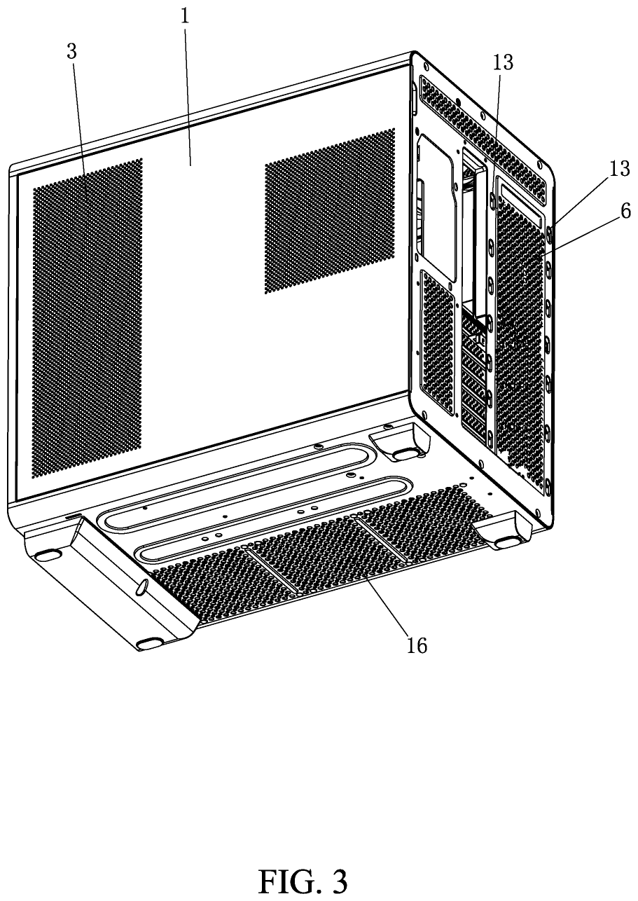

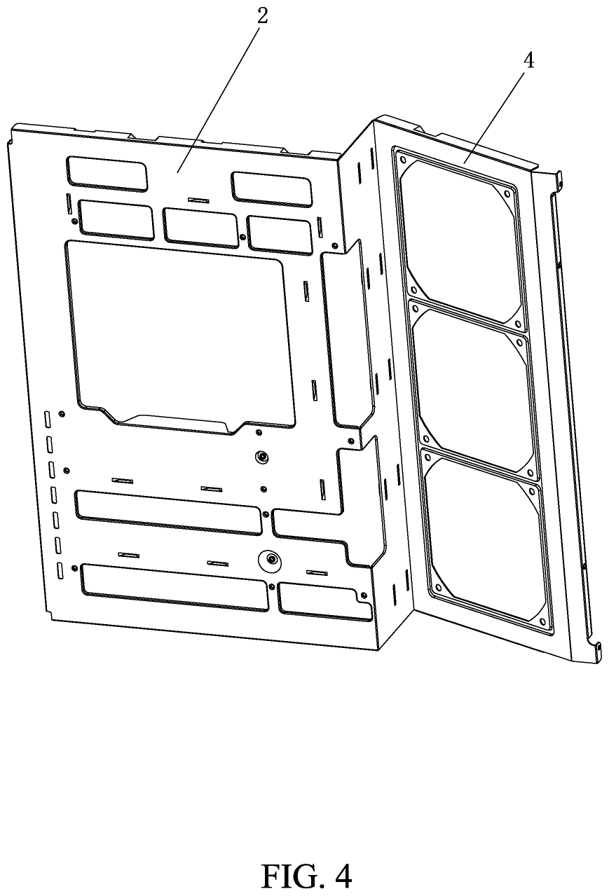

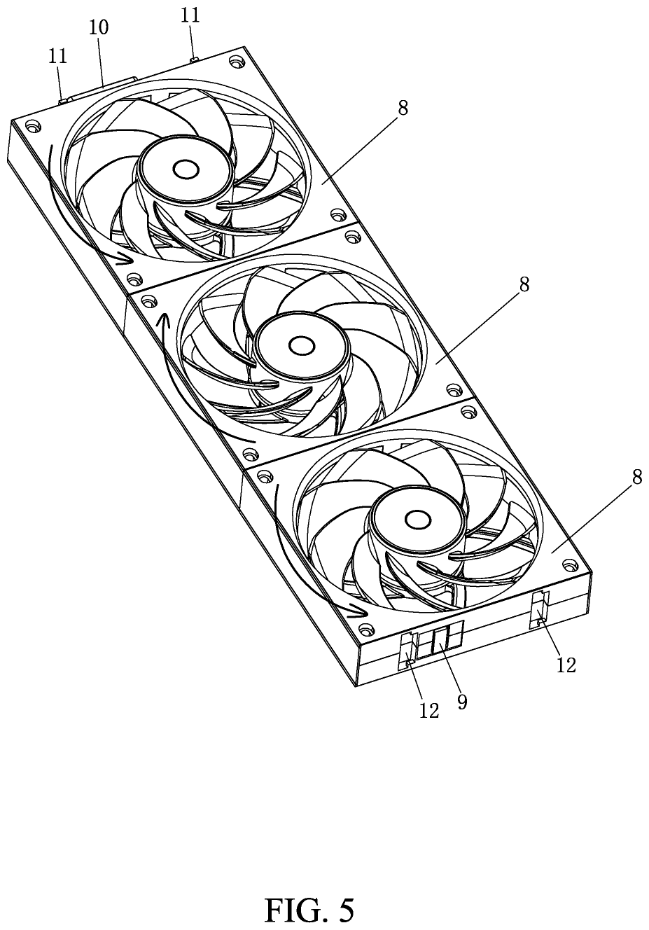

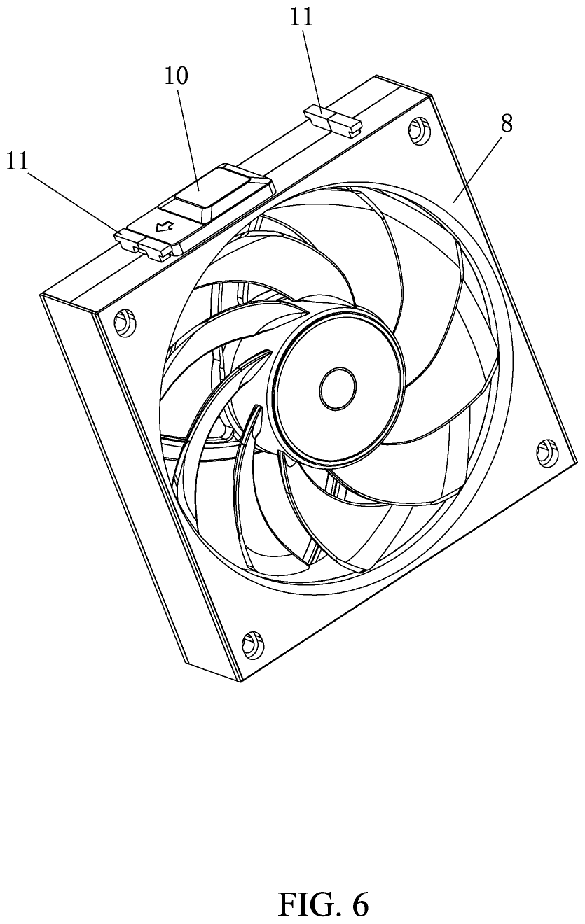

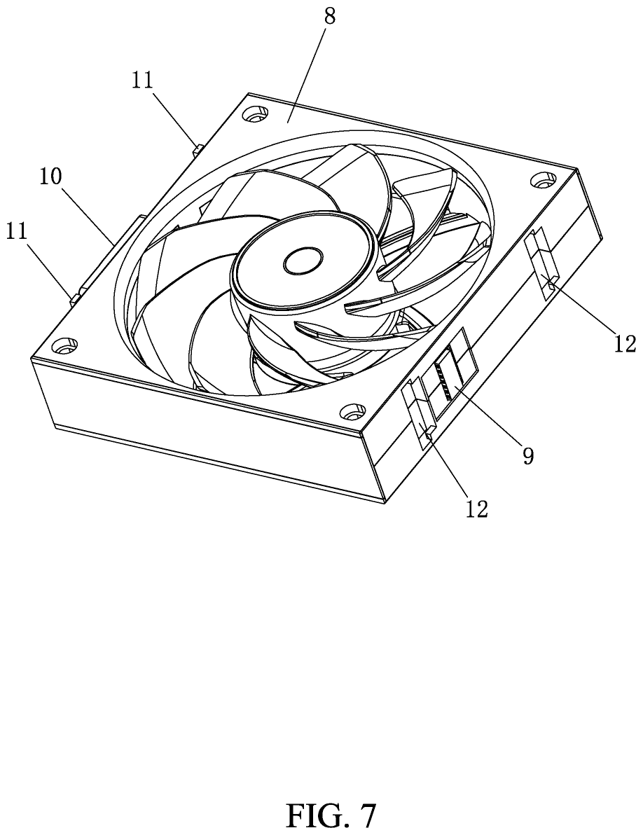

Referring to FIGS. 1-7, the present disclosure provides an efficient cooling case, which includes a square casing 1. The casing 1 is provided with an installation plate 2, and an installation space is formed between the installation plate 2 and a right side plate of the casing 1. The right side plate of the casing 1 is provided with heat dissipation holes 3, and the installation plate 2 is integrally bent to form a fixing plate 4. The heat dissipation holes 3 are correspondingly arranged with the fixing plate 4. The fixing plate 4 is detachably provided with an air inlet and heat dissipation module 5, and the air inlet and heat dissipation module 5 is provided between the installation plate 2 and a front side plate of the casing 1. A rear side plate of the casing 1 is provided with a rear heat dissipation mesh 6, and the rear heat dissipation mesh 6 is detachably provided with an air outlet and heat dissipation module 7; the air inlet and heat dissipation module 5 and/or the air outlet and heat dissipation module 7 include at least two module fans 8 that can be disassembled and spliced together; each of the module fans 8 is square in shape, with a conductive male terminal 9 and a conductive female terminal 10 provided on opposite sides of a frame of each of the module fans 8. Two opposite sides of the frame of each of the module fans 8 are provided with a splicing clamp block 11 and a splicing clamp slot 12, the splicing clamp block 11 and the conductive female terminal 10 are located on the same side of the module fans 8, and the splicing clamp slot 12 and the conductive male terminal 9 are located on the same side of the module fans 8. In two adjacent module fans 8, the splicing clamp block 11 of one module fan 8 is connected to the splicing clamp slot 12 of the other module fan 8, and the conductive female terminal 10 of one module fan 8 is adapted and electrically connected to the conductive male terminal 9 of the other module fan 8; the two adjacent module fans 8 are symmetrically arranged in a mirror image, and rotation directions of fan blades of the two adjacent module fans 8 are opposite.

In practical applications, a motherboard and other electrical components are installed in the installation space. When the motherboard and other electrical components work, they generate a large amount of heat. The air inlet and heat dissipation module 5 and the air outlet and heat dissipation module 7 are activated. The air inlet-and-heat dissipation module 5 forms an airflow of external air, and the airflow enters the casing 1, and the air outlet and heat dissipation module 7 blows the airflow inside the casing 1 out of the casing 1. This airflow can quickly dissipate the heat inside the casing 1; where in the air inlet and heat dissipation module 5 and the air outlet and heat dissipation module 7, due to the mirror setting of adjacent module fans 8 and the opposite rotation directions of the fan blades of adjacent module fans 8, a convergence space is formed between adjacent module fans 8. Therefore, the airflow generated by adjacent module fans 8 flows in the same direction through the convergence space, and there is no convective collision between the two airflows during convergence, effectively reducing turbulence, enhancing wind pressure, and reducing wind noise, thereby improving the cooling effect. In addition, since the adjacent two module fans 8 in the air inlet and heat dissipation module 5 and the air outlet and heat dissipation module 7 are assembled and disassembled quickly, it is not only beneficial for the assembly and molding of the air inlet and heat dissipation module 5 and air outlet and heat dissipation module 7, but also allows for the increase or decrease of the number of the module fans 8 according to the size and application scenario of the casing 1, in order to meet the needs of rapid cooling of the case. The present disclosure forms a fast-cooling airflow through collaborative work of the air inlet and heat dissipation module 5 and the outlet cooling module 7. Combined with the opposite rotation directions of the fan blades of adjacent module fans 8, it greatly reduces turbulence, enhances wind pressure, and reduces wind noise, thereby improving the cooling effect. The module fans 8 can be flexibly spliced, and the number of the module fans 8 can be increased or decreased according to actual needs to ensure efficient cooling and facilitate the replacement and maintenance of individual module fans 8.

In this embodiment, all module fans 8 are arranged in a straight line in the air inlet and heat dissipation module 5 or the air outlet and heat dissipation module 7; the module fans 8 are secured to the fixing plate 4 or the rear heat dissipation mesh 6 via a locking fastener 13.

In this embodiment, a top side plate of the casing 1 is provided with a top heat dissipation mesh 15, and a bottom side plate of the casing 1 is provided with a bottom heat dissipation mesh 16. The top heat dissipation mesh 15 is detachably provided with the air inlet and heat dissipation module 5, and the bottom heat dissipation mesh 16 is detachably provided with the air outlet and heat dissipation module 7. This structural design can also generate longitudinal cooling airflow to further enhance the cooling effect.

In this embodiment, the fixing plate 4 is arranged to be inclined relative to the installation plate 2, and an angle between the fixing plate 4 and the front side plate of the casing 1 is obtuse, and an angle between the fixing plate 4 and a left side plate of the casing 1 is acute. In practical applications, compared to the vertical airflow blowing towards the left side plate of the casing 1, which generates rebound airflow and causes turbulence in the airflow inside the casing 1, the airflow blown into the casing 1 by the air inlet and cooling module 5 of this application forms an obtuse angle with the left side plate of the casing 1. The left side plate of the casing 1 can guide the airflow and direct it towards a direction of the air outlet and heat dissipation module 7, rendering the airflow inside the casing 1 smoother, and it is conducive to improve the rapid cooling effect.

In this embodiment, a circular arc air guide plate is provided at an angle between the front side plate of the casing 1 and the left side plate of the casing 1. The center of the circular arc air guide plate faces an inside of the casing 1. The circular arc air guide plate guides the airflow blown into the air inlet and heat dissipation module 5, reduces wind resistance, and it is conducive to a more stable and faster airflow inside the casing 1.

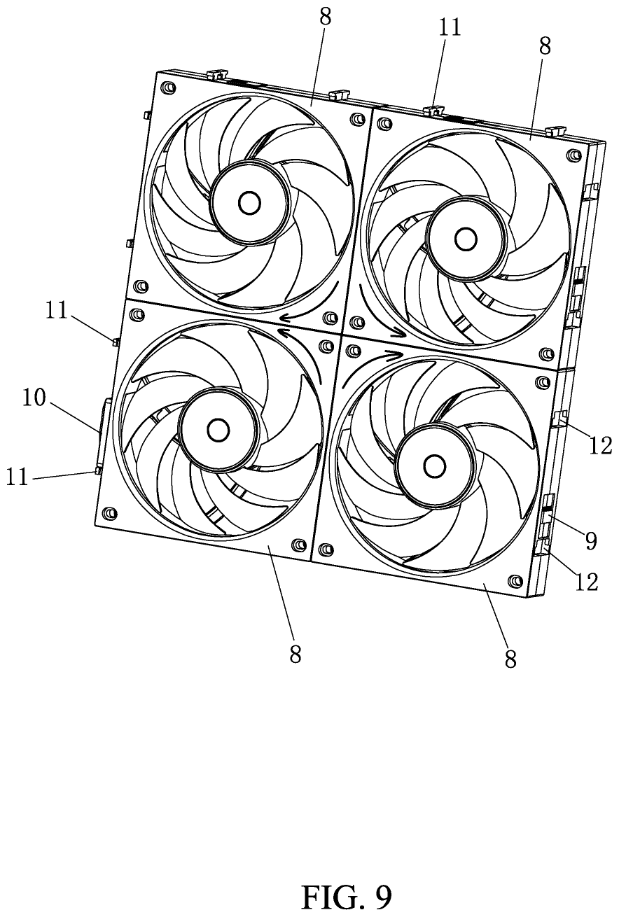

Referring to FIG. 9, in an implementation mode, other two opposite sides of the frame of each of the module fans 8 are also provided with the conductive male terminal 9 and the conductive female terminal 10. Other two opposite sides of the frame of each of the module fans 8 are also provided with the splicing clamp block 11 and the splicing clamp slot 12. The splicing clamp block 11 and the conductive female terminal 10 are located on the same side of the module fans 8, and the splicing clamp slot 12 and the conductive male terminal 9 are located on the same side of the module fans 8. The number of the module fans 8 in the air inlet and heat dissipation module 5 or the air outlet and heat dissipation module 7 is 2N, N≥2, N is a positive integer. In the air inlet and heat dissipation module 5 or the air outlet and heat dissipation module 7, all module fans 8 are arranged in a rectangular array. This structural design is conducive to further increasing the number of the module fans 8, with better adaptability, and wider range of use.

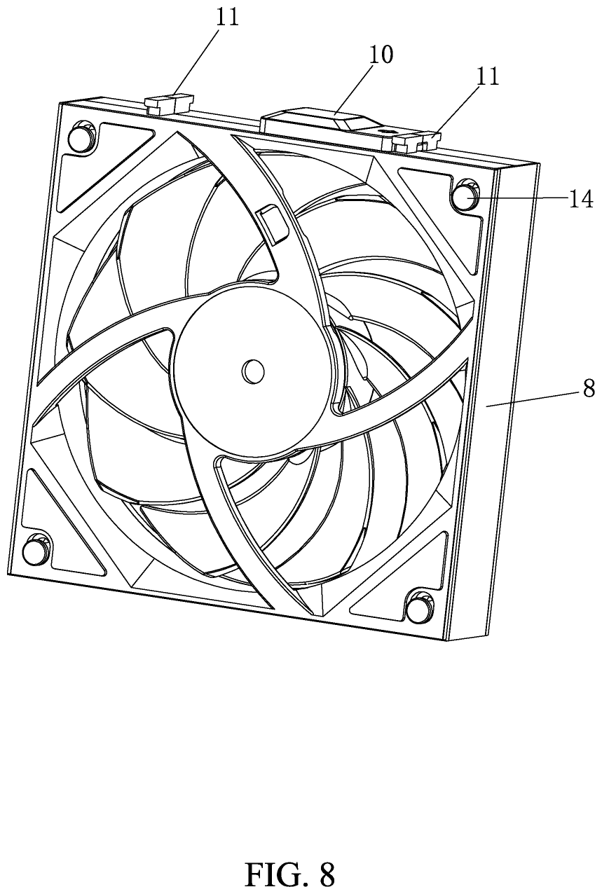

Referring to FIG. 8, in an implementation mode, both the fixing plate 4 and the rear heat dissipation mesh 6 are provided with multiple sets of clamp slot positions. The module fans 8 are provided with a clamp joint shaft 14, and the clamp joint shaft 14 is configured to clamp connection with a set of clamp slot positions. In practical applications, it is beneficial to quickly disassemble and assemble the module fans 8 with the fixing plate 4 or the rear heat dissipation mesh 6 by connecting the clamp joint shaft 14 with the clamp slot positions.

In this embodiment, each set of clamp slot positions has multiple clamp slots, and the clamp joint shaft 14 has multiple clamp shafts, and the multiple clamp shafts are respectively connected to the multiple clamp slots. This structural design ensures a secure assembly between the module fans 8 and the fixing plate 4 or the rear heat dissipation mesh 6.

In an implementation mode, the frame of each of the module fans 8 is provided with magnetic suction components and at least two positioning columns. The fixing plate 4 and the rear heat dissipation mesh 6 are both provided with multiple positioning holes, and the magnetic suction components can be magnetically attracted to the fixing plate 4 or the rear heat dissipation mesh 6. One positioning column and one positioning hole are concave and convex adapted. In an implementation mode, the magnetic suction components can be made of magnets. When assembling the module fans 8, the positioning columns are aligned with the positioning holes, and the magnetic suction components magnetically attract the frame of each of the module fans 8 onto the fixing plate 4 or the rear heat dissipation mesh 6, so that the positioning columns are inserted into the positioning holes, ensuring the positional accuracy and stability of the module fans 8 assembled on the fixing plate 4 or the rear heat dissipation mesh 6, and facilitating the disassembly and assembly of the module fans 8.

All technical features in this embodiment can be freely combined according to actual needs.

The above embodiment is preferred implementation schemes of the present disclosure. Besides that, the present disclosure can also be implemented in other ways. Any obvious replacement without departing from the concept of the present technical solution is within the protection scope of the present disclosure.

What is claimed is:

1. An efficient cooling case, comprising: a square casing, and the casing is provided with an installation plate inside, an installation space is formed between the installation plate and a right side plate of the casing;
the right side plate of the casing is provided with heat dissipation holes, and the installation plate is integrally bent and formed with a fixing plate; the heat dissipation holes correspond to the fixing plate, and the fixing plate is detachably provided with an air inlet and heat dissipation module; the air inlet and heat dissipation module is provided between the installation plate and a front side plate of the casing,
a rear side plate of the casing is provided with a rear heat dissipation mesh, and the rear heat dissipation mesh is detachably provided with an air outlet and heat dissipation module;
the air inlet and heat dissipation module and/or the air outlet and heat dissipation module comprise at least two module fans that are configured to be disassembled and spliced together;
a frame of each of the module fans is square shaped, and two opposite sides of the frame of each of the module fans are respectively provided with a conductive male terminal and a conductive female terminal;
two opposite sides of the frame of each of the module fans are respectively provided with a splicing clamp block and a splicing clamp slot;
the splicing clamp block and the conductive female terminal are provided on the same side of the module fans, and the splicing clamp slot and the conductive male terminal are provided on the same side of the module fans;
in two adjacent module fans, the splicing clamp block of one module fan is clamp connected to the splicing clamp slot of the other module fan, and the conductive female terminal of one module fan is adapted and electrically connected to the conductive male terminal of the other module fan;
two adjacent module fans are symmetrically arranged in a mirror image, and rotation directions of fan blades of the two adjacent module fans are opposite.

2. The efficient cooling case according to claim 1, wherein all module fans in the air inlet and heat dissipation module or the air outlet and heat dissipation module are arranged in a straight line.

3. The efficient cooling case according to claim 1, wherein other two opposite sides of the frame of each of the module fans is further provided with the conductive male terminal and the conductive female terminal, and other two opposite sides of the frame of each of the module fans is further provided with the splicing clamp block and the splicing clamp slot;
the splicing clamp block and the conductive female terminal are provided on the same side of the module fans, and the splicing clamp slot and the conductive male terminal are provided on the same side of the module fans;
the number of module fans in the air inlet and heat dissipation module or the air outlet and heat dissipation module are 2N, N≥2, where N is a positive integer,
all module fans in the air inlet and heat dissipation module or the air outlet and heat dissipation module are arranged in a rectangular array.

4. The efficient cooling case according to claim 1, wherein the fixing plate and the rear heat dissipation mesh are both provided with multiple sets of clamp slot positions, and the module fans are provided with a clamp joint shaft configured to clamp connection with a set of clamp slot positions.

5. The efficient cooling case according to claim 4, wherein each set of clamp slot positions has multiple clamp slots, and the clamp joint shaft has multiple clamp shafts that are respectively connected to the multiple clamp slots.

6. The efficient cooling case according to claim 1, wherein the frame of each of the module fans is provided with magnetic suction components and at least two positioning columns, the fixing plate and the rear heat dissipation mesh are both provided with multiple positioning holes, and the magnetic suction components are configured to be magnetically attracted to the fixing plate or the rear heat dissipation mesh, and one positioning column and one positioning hole are concave and convex adapted.

7. The efficient cooling case according to claim 1, wherein the module fans are fixed to the fixing plate or the rear heat dissipation mesh by a locking fastener.

8. The efficient cooling case according to claim 1, wherein a top side plate of the casing is provided with a top heat dissipation mesh, a bottom side plate of the casing is provided with a bottom heat dissipation mesh,
the top heat dissipation mesh is detachably provided with the air inlet and heat dissipation module, and the bottom heat dissipation mesh is detachably provided with the air outlet and heat dissipation module.

9. The efficient cooling case according to claim 1, wherein the fixing plate is arranged to be inclined relative to the installation plate, and an angle between the fixing plate and the front side plate of the casing is obtuse.

10. The efficient cooling case according to claim 1, wherein a circular arc air guide plate is provided at an angle between the front side plate of the casing and the left side plate of the casing.
